(19) United States
(12) Patent Application Publication
(10) Pub. No.: US 2025/0273929 A1
(43) Pub. Date: Aug. 28, 2025

(54) LIGHT-EMITTING SYSTEM

(71) Applicant: Panasonic Intellectual Property Management Co., Ltd., Osaka (JP)

(72) Inventors: Norishige NANAI, Osaka (JP); Yosuke MIZOKAMI, Hyogo (JP); Toshihiko SATO, Osaka (JP)

(73) Assignee: Panasonic Intellectual Property Management Co., Ltd., Osaka (JP)

(21) Appl. No.: 18/289,567

(22) PCT Filed: Mar. 10, 2022
(86) PCT No.: PCT/JP2022/010524

§ 371 Date: Jun. 11, 2024

(30) Foreign Application Priority Data
May 14, 2021 (JP) 2021-082734

(51) Int. Cl. H01S 5/065; H01S 5/06; H01S 5/0683; H01S 5/40

(52) U.S. Cl. CPC H01S 5/0656; H01S 5/0611; H01S 5/0683; H01S 5/4012

(57) ABSTRACT

A first wavelength-converting member is an optical fiber containing a first wavelength-converting element. The first wavelength-converting element is excited not only by excitation light emitted from a first light source unit to produce a spontaneous emission of light having a longer wavelength than the excitation light but also by amplified spontaneous emission of light. A second light source unit emits a seed light ray causing the first wavelength-converting element excited to produce a stimulated emission of light. A second wavelength-converting element contained in a second wavelength-converting member produces light having a wavelength different from both the excitation light and the seed light ray. The light output member outputs light coming from the second wavelength-converting member. A detector detects returning light traveling from the first wavelength-converting member toward the first light source unit by way of a light guiding section between the first light source unit and the first wavelength-converting member.

### TECHNICAL FIELD

The present disclosure generally relates to a light-emitting system, and more particularly relates to a light-emitting system that uses excitation light.

### BACKGROUND ART

A light-emitting device including a light source, a light guiding member, an optical member, and a detecting member has been proposed in the known art (see, for example, Patent Literature 1). In the light-emitting device disclosed in Patent Literature 1, the light coming from the light source is propagated through the light guiding member to reach the optical member provided at the tip of the light guiding member. Most of the light that has reached the optical member is transmitted through the optical member to be output to the space outside the light-emitting device, while part of the light is reflected by the optical member to propagate, as returning light, toward the light source. The detecting member is provided between the light guiding member and the light source to detect this returning light.

The light source includes, as a semiconductor light-emitting element, a semiconductor laser diode, of which the principal wavelength corresponds to the wavelength of blue light. The optical member includes a light-transmitting member and a wavelength-converting material. The wavelength-converting material is a phosphor material contained in the light-transmitting member and at least partially absorbing the light coming from the semiconductor light-emitting element to produce light having a different wavelength.

The light-emitting device of Patent Literature 1 outputs the light from the wavelength-converting material of the optical member to the space outside the light-emitting device. Thus, a light output member thereof, through which the light is output to the space outside the light-emitting device, comes to have an increased temperature.

### CITATION LIST

### Patent Literature

Patent Literature 1: JP 2008-122838 A

### SUMMARY OF INVENTION

An object of the present disclosure is to provide a light-emitting system having the ability to reduce an increase in the temperature of the light output member and detect the returning light.

A light-emitting system according to an aspect of the present disclosure includes a first light source unit, a first wavelength-converting member, a second light source unit, a second wavelength-converting member, a light output member, and a detector. The first light source unit emits excitation light. The first wavelength-converting member is an optical fiber containing a first wavelength-converting element. The first wavelength-converting element may be excited not only by the excitation light to produce a spontaneous emission of light having a longer wavelength than the excitation light but also by an amplified spontaneous emission of light. The second light source unit emits a seed light ray causing the first wavelength-converting element that has been excited by either the excitation light or the amplified spontaneous emission of light to produce a stimulated emission of light. The second wavelength-converting member contains a second wavelength-converting element. The second wavelength-converting element is excited by either light produced by the first wavelength-converting element or the excitation light to produce light having a wavelength different from both a wavelength of the excitation light and a wavelength of the seed light ray. The light output member outputs the light coming from the second wavelength-converting member. The detector detects returning light traveling from the first wavelength-converting member toward the first light source unit by way of a light guiding section between the first light source unit and the first wavelength-converting member.

### BRIEF DESCRIPTION OF DRAWINGS

FIG. 1 illustrates a configuration for a light-emitting system according to a first embodiment;

FIG. 2A is a cross-sectional view of an optical fiber serving as a first wavelength-converting member in the light-emitting system;

FIG. 2B is a cross-sectional view of an optical fiber serving as a second wavelength-converting member in the light-emitting system;

FIGS. 3A-3C illustrate an operating principle of the first wavelength-converting member of the light-emitting system;

FIG. 4 illustrates a configuration for a light-emitting system according to a second embodiment;

FIG. 5 illustrates a configuration for a light-emitting system according to a third embodiment; and

FIG. 6 illustrates a configuration for a light-emitting system according to a fourth embodiment.

### DESCRIPTION OF EMBODIMENTS

The drawings to be referred to in the following description of first to fourth embodiments are all schematic representations. That is to say, the ratio of the dimensions (including thicknesses) of respective constituent elements illustrated on the drawings does not always reflect their actual dimensional ratio.

### First Embodiment

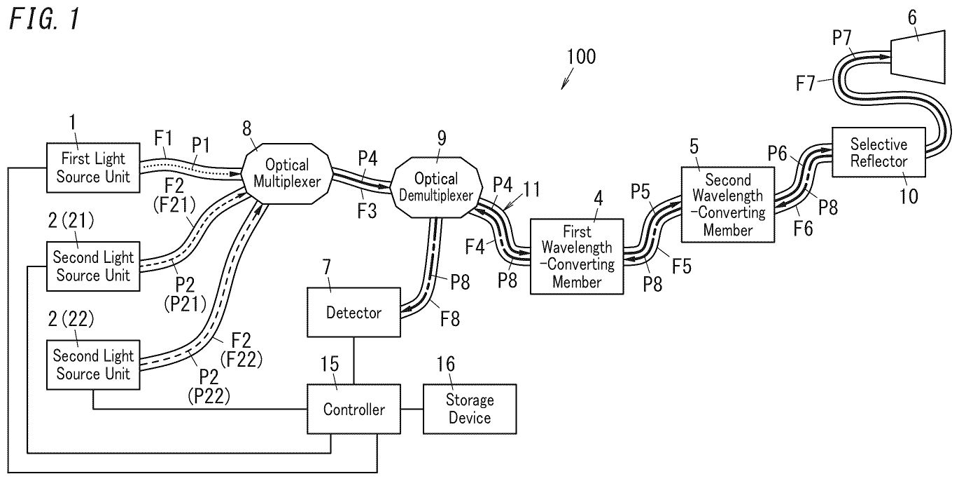

A light-emitting system 100 according to a first embodiment will be described with reference to FIGS. 1, 2A, 2B, 3A, 3B, and 3C.

### (1) Overview

As shown in FIG. 1, the light-emitting system 100 includes a first light source unit 1, a first wavelength-converting member 4, a plurality of (e.g., two) second light source units 2, a second wavelength-converting member 5, a light output member 6, and a detector 7. The first light source unit 1 emits excitation light P1. The first wavelength-converting member 4 is configured as an optical fiber containing a first wavelength-converting element (such as Pr³⁺). The first wavelength-converting element may be excited by the excitation light P1 to produce a spontaneous emission of light having a longer wavelength than the excitation light P1 and may also be excited by an amplified spontaneous emission of light. Each of the second light source units 2 emits a seed light ray P2 causing the first wavelength-converting element that has been excited by either the excitation light P1 or the amplified spontaneous emission of light to produce a stimulated emission of light P3. The second wavelength-converting member 5 contains a second wavelength-converting element (such as Dy³⁺). The second wavelength-converting element is excited by the excitation light P1 to produce light having a wavelength different from both the wavelength of the excitation light P1 and the wavelength of the seed light ray P2. The light output member 6 outputs the light coming from the second wavelength-converting member 5. The detector 7 detects returning light P8 traveling from the first wavelength-converting member 4 toward the first light source unit 1 by way of a light guiding section 11 between the first light source unit 1 and the first wavelength-converting member 4.

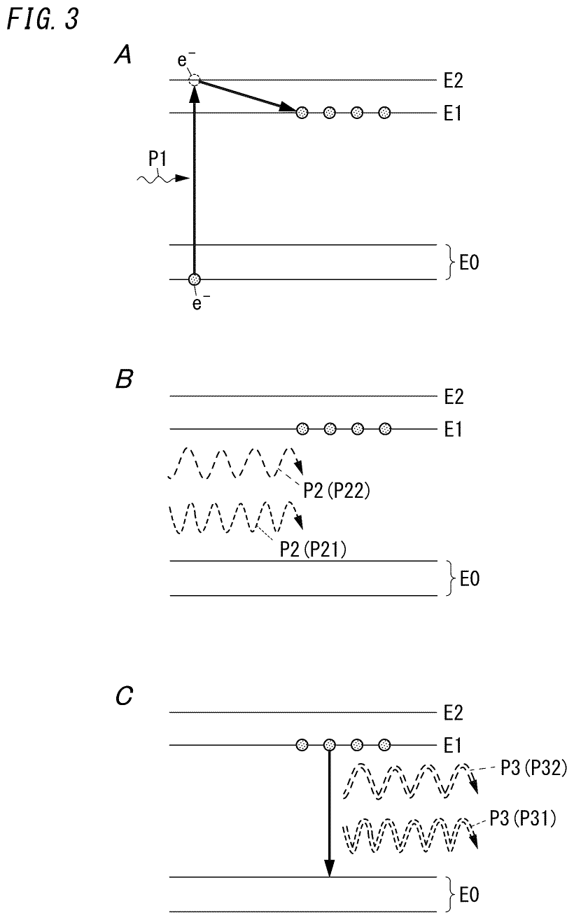

The light-emitting system 100 makes the excitation light P1 and the seed light ray P2 incident on the first wavelength-converting member 4. The excitation light P1 excites the first wavelength-converting element. The seed light ray P2 causes the first wavelength-converting element that has been excited by the excitation light P1 to produce a stimulated emission of light P3 (refer to FIG. 3C). From the first wavelength-converting member 4, light P5 including the excitation light P1 and the stimulated emission of light P3 emerges. FIGS. 3A-3C illustrate the principle of operation of the first wavelength-converting member 4 of the light-emitting system 100. In FIGS. 3A, 3B, and 3C, the ordinate represents the energy of electrons. The upward arrow shown in FIG. 3A indicates absorption of the excitation light P1. The downward arrow shown in FIG. 3C indicates transition about a spontaneous emission of light or a stimulated emission of light P3. In the first wavelength-converting member 4, an electron e⁻ in a ground state E0 (including a plurality of energy levels) of the first wavelength-converting element is excited to an excitation level E2 by the excitation light P1 that has been incident on the first wavelength-converting member 4. Then, the electron e⁻ at the excitation level E2 makes a transition to a metastable level E1, which is an energy level lower than the excitation level E2. Thereafter, the stimulated emission of light P3 (P32) is produced when the electron e⁻ at the metastable level E1 is caused to make a transition to one of the highest ones of the plurality of energy levels (hereinafter referred to as a “second energy level”) of the ground state E0 by the seed light ray P2 (P22). The wavelength of the seed light ray P2 (P22) corresponds to the difference in energy between the metastable level E1 and the second energy level, for example. In addition, a stimulated emission of light P3 (P31) is also produced when the electron e⁻ at the metastable level E1 is caused to make a transition to another energy level (hereinafter referred to as a “first energy level”), lower than the second energy level out of the plurality of energy levels of the ground state E0, by the seed light ray P2 (P21). The wavelength of the seed light ray P2 (P21) corresponds to the difference in energy between the metastable level E1 and the first energy level.

The second wavelength-converting member 5 causes the electron in the ground state of the second wavelength-converting element to be excited to the excitation level of the second wavelength-converting element by the excitation light P1. Then, the second wavelength-converting member 5 causes the electron at the excitation level to make a transition to the metastable level of the second wavelength-converting element. Thereafter, when the electron at the metastable level makes a transition to an energy level lower than the metastable level, light having a wavelength different from both the wavelength of the excitation light P1 and the wavelength of the seed light ray is produced.

The light-emitting system 100 may be used, for example, for lighting purposes. Examples of lighting may include, without limitation, a downlight for use indoors, a lighting system for use in refrigerated warehouses, a lighting system for use in outdoor tennis courts, a lighting system for use in tunnels, a lighting system for collecting fish on a fishing boat, and a headlight for vehicles. In addition, the light-emitting system 100 is not necessarily used for lighting purposes but is also applicable for use in a projection system including a projector.

### (2) Configuration for Light-Emitting System

As shown in FIG. 1, the light-emitting system 100 includes the first light source unit 1, the first wavelength-converting member 4, the plurality of (e.g., two) second light source units 2, the second wavelength-converting member 5, the light output member 6, and the detector 7. The light-emitting system 100 further includes a controller 15. The controller 15 controls output of each of the first light source unit 1 and the second light source unit 2. The light-emitting system 100 further includes a storage device 16. The light-emitting system 100 further includes a selective reflector 10. The light-emitting system 100 further includes a first optical fiber F1, a plurality of (e.g., two) second optical fibers F2, a third optical fiber F3, a fourth optical fiber F4, a fifth optical fiber F5, a sixth optical fiber F6, a seventh optical fiber F7, an eighth optical fiber F8, an optical multiplexer 8, and an optical demultiplexer 9. The two second light source units 2 may, for example, emit seed light rays P2 with mutually different wavelengths. In the following description, one of the two second light source units 2 will be hereinafter sometimes referred to as a “second light source unit 21” and the other second light source unit 2 will be hereinafter referred to as a “second light source unit 22” for convenience sake. In addition, the seed light ray P2 emitted from the second light source unit 21 will be hereinafter sometimes referred to as a “seed light ray P21” and the seed light ray P2 emitted from the second light source unit 22 will be hereinafter sometimes referred to as a “seed light ray P22.” Furthermore, of the two second optical fibers F2, the second optical fiber F2 provided for the second light source unit 21 will be hereinafter sometimes referred to as a “second optical fiber F21” and the second optical fiber F2 provided for the second light source unit 22 will be hereinafter sometimes referred to as a “second optical fiber F22.”

### (2.1) First Light Source Unit

The first light source unit 1 emits the excitation light P1 to excite the first wavelength-converting element contained in the first wavelength-converting member 4. The excitation light P1 coming from the first light source unit 1 is incident on the first wavelength-converting member 4. More specifically, the excitation light P1 coming from the first light source unit 1 is incident on the first wavelength-converting member 4 via the first optical fiber F1, the optical multiplexer 8, the third optical fiber F3, the optical demultiplexer 9, and the fourth optical fiber F4.

The first light source unit 1 includes, for example, a laser light source. The laser light source emits a laser beam. The excitation light P1 coming from the first light source unit 1 (i.e., the laser beam emitted from the laser light source) is incident on the first wavelength-converting member 4. The laser light source may be, for example, a semiconductor laser diode that emits a blue laser beam. In this case, the excitation light P1 may have a wavelength equal to or longer than 440 nm and equal to or shorter than 450 nm, for example.

### (2.2) First Wavelength-Converting Member

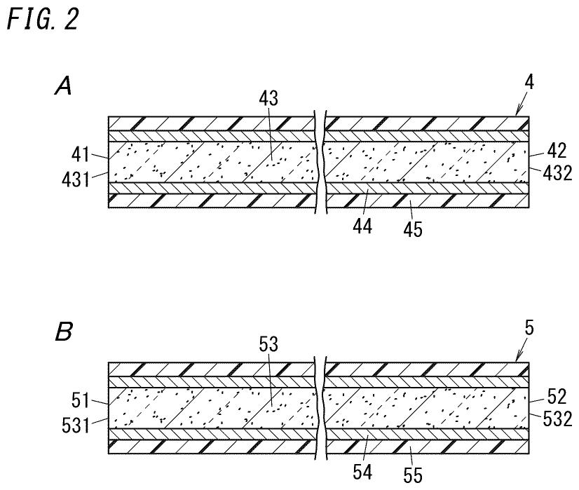

The first wavelength-converting member 4 is an optical fiber containing the first wavelength-converting element (such as Pr³⁺). The first wavelength-converting member 4 includes a core 43, cladding 44, and a jacket 45 as shown in FIG. 2A. The cladding 44 covers the outer peripheral surface (side surface) of the core 43. The jacket 45 covers the outer peripheral surface (side surface) of the cladding 44. A cross section, taken along a plane perpendicular to the optical axis, of the core 43 has a circular shape. The cladding 44 is disposed coaxially with the core 43.

The core 43 includes a light-transmitting material and the first wavelength-converting element. The concentration of the first wavelength-converting element in the core 43 may or may not be uniform along the entire length of the core 43. The core 43 may have a diameter equal to or greater than 25 μm and equal to or less than 500 μm, for example. The first wavelength-converting member 4 may have a length equal to or greater than 3 m and equal to or less than 10 m, for example. It is preferable that the lower the concentration of the first wavelength-converting element in the first wavelength-converting member 4 is, the longer the first wavelength-converting member 4 is. The optical fiber including the first wavelength-converting member 4 may have a numerical aperture of 0.22, for example.

The refractive index of the core 43 may be substantially equal to the refractive index of the light-transmitting material that is a main component of the core 43.

The light-transmitting material may be, for example, a fluoride, an oxide, or a nitride. The fluoride may be glass fluoride, for example. The oxide may be a silicon oxide or quartz, for example.

The first wavelength-converting element is a rare-earth element. In this embodiment, the first wavelength-converting element includes an element selected from the group consisting of, for example, Pr, Tb, Ho, Dy, Er, Eu, Nd, and Mn. The first wavelength-converting element is contained as an ion of a rare-earth element in the core 43, e.g., contained as an ion of Pr (i.e., Pr³⁺). In this case, the first wavelength-converting element may be excited by either the excitation light P1 or an amplified spontaneous emission (ASE) of light. The amplified spontaneous emission (ASE) of light is produced by amplifying the spontaneous emission of light, emitted from a different first wavelength-converting element other than the first wavelength-converting element itself, as an internal seed light ray. Through such excitation, the first wavelength-converting element emits not only an ASE unique to the element of the first wavelength-converting element but also a stimulated emission of light having the same wavelength as the seed light ray P2 (hereinafter referred to as “external seed light ray P2”), thus emitting them as the stimulated emission of light P3. The wavelengths of the ASE and the external seed light ray P2 are longer than the wavelength of the excitation light P1 (which may be equal to or longer than 440 nm and equal to or shorter than 450 nm, for example). The wavelength of the seed light ray P2 will be described later in the “(2.3) Second light source unit” section.

Pr³⁺ is a wavelength-converting element that may emit either an ASE or amplified seed light ray in the cyan to red range. The intensity of the stimulated emission of light depends on the respective intensities of the internal seed light ray (the spontaneous emission of light) and the external seed light ray.

The refractive index of the cladding 44 is less than the refractive index of the core 43. The cladding 44 does not contain the first wavelength-converting element contained in the core 43.

The material of the jacket 45 may be a resin, for example. The jacket 45 may have an outside diameter equal to or less than 1 mm, for example.

The first wavelength-converting member 4 includes a light inlet portion 41 and a light outlet portion 42. In the first wavelength-converting member 4, the light inlet portion 41 is constituted by a first end surface 431 of the core 43 and the light outlet portion 42 is constituted by a second end surface 432 of the core 43.

In the first wavelength-converting member 4, light P4, including the excitation light P1 coming from the first light source unit 1 and the multiple seed light rays P2 coming from the plurality of second light source units 2, is incident on the light inlet portion 41. More specifically, the excitation light P1 coming from the first light source unit 1 is incident on the light inlet portion 41 of the first wavelength-converting member 4 via the first optical fiber F1, the optical multiplexer 8, the third optical fiber F3, the optical demultiplexer 9, and the fourth optical fiber F4. In addition, the seed light ray P21 coming from the second light source unit 21 is also incident on the light inlet portion 41 of the first wavelength-converting member 4 via the second optical fiber F21, the optical multiplexer 8, the third optical fiber F3, the optical demultiplexer 9, and the fourth optical fiber F4. Furthermore, the seed light ray P22 coming from the second light source unit 22 is further incident on the light inlet portion 41 of the first wavelength-converting member 4 via the second optical fiber F21, the optical multiplexer 8, the third optical fiber F3, the optical demultiplexer 9, and the fourth optical fiber F4. The light outlet portion 42 of the first wavelength-converting member 4 outputs light P5 including the excitation light P1 and the stimulated emission of light P3 including the ASE.

### (2.3) Second Light Source Units

The light-emitting system 100 includes a plurality of (e.g., two) second light source units 2.

The second light source unit 21 emits the seed light ray P21. The seed light ray P21 coming from the second light source unit 21 is incident on the light inlet portion 41 of the first wavelength-converting member 4. More specifically, the seed light ray P21 coming from the second light source unit 21 is incident on the light inlet portion 41 of the first wavelength-converting member 4 via the second optical fiber F21, the optical multiplexer 8, the third optical fiber F3, the optical demultiplexer 9, and the fourth optical fiber F4.

The second light source unit 22 emits the seed light ray P22. The seed light ray P22 coming from the second light source unit 22 is incident on the light inlet portion 41 of the first wavelength-converting member 4. More specifically, the seed light ray P22 coming from the second light source unit 22 is incident on the light inlet portion 41 of the first wavelength-converting member 4 via the second optical fiber F22, the optical multiplexer 8, the third optical fiber F3, the optical demultiplexer 9, and the fourth optical fiber F4.

The second light source unit 21 may be a semiconductor laser diode that emits a green light ray, for example. The second light source unit 22 may be a semiconductor laser diode that emits a red light ray, for example. If the first wavelength-converting element of the first wavelength-converting member 4 includes Pr³⁺, then the wavelength of the green seed light ray P21 is preferably about 520 nm, for example, and the wavelength of the red seed light ray P22 is preferably about 640 nm, for example. The plurality of second light source units 2 are light sources, each of which emits quasi-monochromatic light. As used herein, the “quasi-monochromatic light” refers to light falling within a narrow wavelength range (with a width of 10 nm, for example). The number of the second light source units 2 included in the light-emitting system 100 does not have to be two but may also be three or more or even one. If the light-emitting system 100 includes three second light source units 2, then the light-emitting system 100 may include, as the three second light source units 2, a semiconductor laser diode that emits a green light ray, a semiconductor laser diode that emits a red light ray, and a semiconductor laser diode that emits an orange light ray. The orange light ray preferably has a wavelength of about 600 nm, for example.

### (2.4) Second Wavelength-Converting Member

The second wavelength-converting member 5 outputs at least light having a different wavelength from any one of the excitation light P1, the seed light ray P21, or the seed light ray P22. However, this is only an example and should not be construed as limiting. Alternatively, the second wavelength-converting member 5 may also output light, of which the wavelength is as long as at least one of the wavelength of the excitation light P1, the wavelength of the seed light ray P21, or the wavelength of the seed light ray P22.

The second wavelength-converting member 5 is an optical fiber containing the second wavelength-converting element (such as Dy³⁺). The second wavelength-converting member 5 includes a core 53, cladding 54, and a jacket 55 as shown in FIG. 2B. The cladding 54 covers the outer peripheral surface (side surface) of the core 53. The jacket 55 covers the outer peripheral surface (side surface) of the cladding 54. A cross section, taken along a plane perpendicular to the optical axis, of the core 53 has a circular shape. The cladding 54 is disposed coaxially with the core 53.

The core 53 includes a light-transmitting material and the second wavelength-converting element. The concentration of the second wavelength-converting element in the core 53 may or may not be uniform along the entire length of the core 53. The core 53 may have a diameter equal to or greater than 25 μm and equal to or less than 500 μm, for example. The second wavelength-converting member 5 may have a length equal to or greater than 3 m and equal to or less than 10 m, for example. It is preferable that the lower the concentration of the second wavelength-converting element in the second wavelength-converting member 5 is, the longer the second wavelength-converting member 5 is. The optical fiber including the second wavelength-converting member 5 may have a numerical aperture of 0.22, for example.

The refractive index of the core 53 may be substantially equal to the refractive index of the light-transmitting material that is a main component of the core 53.

The light-transmitting material may be, for example, a fluoride, an oxide, or a nitride. The fluoride may be glass fluoride, for example. The oxide may be a silicon oxide or quartz, for example.

The second wavelength-converting element is a rare-earth element. In this embodiment, the second wavelength-converting element includes an element selected from the group consisting of, for example, Pr, Tb, Ho, Dy, Er, Eu, Nd, and Mn. The second wavelength-converting element is contained as an ion of a rare-earth element in the core 53, e.g., contained as an ion of Dy (i.e., Dy³⁺). In this case, the second wavelength-converting element may be excited by either the excitation light P1 or an amplified spontaneous emission (ASE) of light. The amplified spontaneous emission (ASE) of light is produced by amplifying the spontaneous emission of light, emitted from a different second wavelength-converting element other than the second wavelength-converting elements itself, as an internal seed light ray. Through such excitation, the second wavelength-converting element emits not only an ASE unique to the element of the second wavelength-converting element but also a stimulated emission of light having the same wavelength as the external seed light ray P2, thus emitting them as the stimulated emission of light P3. The wavelengths of the ASE and the external seed light ray P2 are longer than the wavelength of the excitation light P1 (which may be equal to or longer than 440 nm and equal to or shorter than 450 nm, for example).

Dy³⁺ may be excited by absorbing an ASE produced from Pr³⁺ to produce an ASE having a wavelength unique to Dy³⁺.

The refractive index of the cladding 54 is less than the refractive index of the core 53. The cladding 54 does not contain the first wavelength-converting element contained in the core 53.

The material of the jacket 55 may be a resin, for example. The jacket 55 may have an outside diameter equal to or less than 1 mm, for example.

The second wavelength-converting member 5 includes a light inlet portion 51 and a light outlet portion 52. In the second wavelength-converting member 5, the light inlet portion 51 is constituted by a first end surface 531 of the core 53 and the light outlet portion 52 is constituted by a second end surface 532 of the core 53. Light P5, including the excitation light P1 coming from the first light source unit 1, the multiple seed light rays P2 coming from the plurality of second light source units 2, and the light produced by the first wavelength-converting member 4, is incident on the light inlet portion 51 of the second wavelength-converting member 5. More specifically, the light P5 coming from the first wavelength-converting member 4 propagates through the fifth optical fiber F5 to be incident on the light inlet portion 51 of the second wavelength-converting member 5. The light outlet portion 52 of the second wavelength-converting member 5 outputs light P6 including the excitation light P1 and the stimulated emission of light P3 including the ASE. The stimulated emission of light P3 emerges from not only the light outlet portion 52 but also the light inlet portion 51 as well.

### (2.5) Light Output Portion

The light output member 6 outputs the light P7 coming from the second wavelength-converting member 5. The light P7 forms part of the light P6 emerging from the second wavelength-converting member 5 which has been transmitted through the selective reflector 10. The light P7 coming from the second wavelength-converting member 5 may, for example, propagate through the seventh optical fiber F7 to be output from the light output member 6. If the light-emitting system 100 is applied to a lighting system, then the light output member 6 is a lighting unit that outputs, into an external space, the light P7 coming from the second wavelength-converting member 5. The lighting unit holds, for example, a second end portion, opposite from a first end portion closer to the second wavelength-converting member 5, of the seventh optical fiber F7. The lighting unit may include an optical member for controlling the distribution of the light output from the second end portion of the seventh optical fiber F7. The optical member may be, for example, a lens or a reflector. If the light-emitting system 100 is used as a down light, then the lighting unit may be fitted into a through hole of the ceiling of a building, for example. In that case, part of the seventh optical fiber F7 will be hidden behind the ceiling and a wall of the building, which form a structure for holding the lighting unit. In other words, part of the seventh optical fiber F7 is installed on the back of the ceiling and the wall. The lighting unit may be mounted to the ceiling with, for example, a flange protruding outward from the bottom of the lighting unit and a plurality of leaf springs to clamp the ceiling between the flange and themselves. Alternatively, the lighting unit may also be mounted onto the ceiling with, for example, a mounting bracket and a plurality of mounting springs. If the light-emitting system 100 is applied to a projection system including a projector, then the light output member 6 may be, for example, a projection lens of the projector.

### (2.6) Detector

The detector 7 detects returning light P8 traveling from the first wavelength-converting member 4 toward the first light source unit 1 by way of a light guiding section 11 between the first light source unit 1 and the first wavelength-converting member 4. In the light-emitting system 100 according to the first embodiment, the light guiding section 11 between the first light source unit 1 and the first wavelength-converting member 4 includes the first optical fiber F1, the optical multiplexer 8, the third optical fiber F3, the optical demultiplexer 9, and the fourth optical fiber F4. In the light-emitting system 100 according to the first embodiment, the returning light P8 is split by the optical demultiplexer 9 in the light guiding section 11 between the first light source unit 1 and the first wavelength-converting member 4 to be incident on the detector 7. The returning light P8 demultiplexed by the optical demultiplexer 9 propagates through the eighth optical fiber F8 to be incident on the detector 7.

The detector 7 detects characteristic light produced by the second wavelength-converting member 5. As used herein, the “characteristic light produced by the second wavelength-converting member 5” refers to light different from not only a plurality of light rays with multiple wavelengths produced by the first wavelength-converting element (such as Pr³⁺) of the first wavelength-converting member 4 but also light having a wavelength at which the first wavelength-converting element is absorbed. Suppose, for example, the light-transmitting material of the first wavelength-converting member 4 is a glass fluoride, the first wavelength-converting element is Pr³⁺, the light-transmitting material of the second wavelength-converting member 5 is a glass fluoride, and the second wavelength-converting element is Dy³⁺. In that case, the characteristic light produced by the second wavelength-converting member 5 may be, for example, either light having a wavelength of 660 nm and produced by the second wavelength-converting element Dy³⁺ or light having a wavelength of 755 nm and produced by Dy³⁺. The light detected by the detector 7 is preferably light falling within a deep red to near infrared range of the spectrum which is not used for adjusting the color by the light-emitting system 100.

The detector 7 may include, for example, a photodiode as a photoelectric transducer element. The output signal of the detector 7 varies according to the light quantity of the characteristic light.

If the wavelength of the characteristic light produced by the second wavelength-converting member 5 is relatively significantly different from the wavelength of the spontaneous emission of light produced by the first wavelength-converting element, then the light may be selectively guided to the detector 7 with the wavelength of the characteristic light produced by the second wavelength-converting member 5 selected by the optical demultiplexer 9. On the other hand, if the wavelength of the characteristic light is close to the wavelength of the spontaneous emission of light produced by the first wavelength-converting element, then an optical element having the ability to select the characteristic light is preferably provided for either the detector 7 or between the optical demultiplexer 9 and the detector 7. Examples of such optical elements having the ability to select the characteristic light include a multilayer film filter, a prism, a multilayer film mirror, and a diffraction grating.

Also, if the characteristic light included in the returning light P8 cannot be selectively split by the optical demultiplexer 9, then the light-emitting system 100 is configured to allow the detector 7 to selectively detect the characteristic light.

### (2.7) Controller and Storage Device

The controller 15 controls the output of the first light source unit 1. In addition, the controller 15 also controls the respective outputs of the plurality of second light source units 2. That is to say, the controller 15 may control the respective outputs of the first light source unit 1, the second light source unit 21, and the second light source unit 22. This allows the controller 15 to adjust the respective intensities of the excitation light P1, the seed light ray P21, and the seed light ray P22. The controller 15 may adjust the chromaticity of the light P7 output from the light output member 6 by controlling the first light source unit 1, the second light source unit 21, and the second light source unit 22 on an individual basis. In short, providing the controller 15 for the light-emitting system 100 allows the light-emitting system 100 to control the color of the light P7 output from the light output member 6.

In the light-emitting system 100, the controller 15 controls the output of at least one of the first light source unit 1, the second light source unit 21, or the second light source unit 22 based on intensity of detected light. The detected light forms part of the returning light P8 incident on the detector 7. The detected light has a wavelength different from both the wavelength of the excitation light P1 and the wavelength of the seed light ray P2. The detected light may be, for example, a light ray having one wavelength (i.e., the characteristic light described above) out of a plurality of light rays having multiple wavelengths and produced by the second wavelength-converting element. The detected light may have a wavelength of 650 nm, for example.

The storage device 16 stores, in advance, relation information about a relation between a set of conditions for driving the first light source unit 1 and the plurality of second light source units 2 and the intensity of the detected light as detected by the detector 7. The controller 15 controls at least one of the first light source unit 1, the second light source unit 21, or the second light source unit 22 in accordance with the intensity of the detected light as detected by the detector 7 and the relation information stored in the storage device 16.

As used herein, the set of conditions for driving the first light source unit 1 and the second light source units 2 refers to a drive current for the semiconductor laser diode in the first light source unit 1 and a drive current for the semiconductor laser diode in each of the plurality of second light source units 2. The relation information may be, for example, information about the relation between the drive current for the semiconductor laser diode in the first light source unit 1, the drive current for the semiconductor laser diode in each of the plurality of second light source units 2, and the intensity of the detected light that has been detected by the detector 7. The relation information is stored on a table in the storage device 16.

The controller 15 controls at least one of the first light source unit 1 or the plurality of second light source units 2 to make the intensity of the detected light that has been detected by the detector 7 under the current set of conditions for driving the first light source unit 1 and the plurality of second light source units 2 closer to the intensity of the detected light associated with the corresponding set of driving conditions in the relation information stored in the storage device 16.

When finding the intensity of the detected light that has been detected by the detector 7 less than a threshold value stored in the storage device 16, the controller 15 decreases the respective outputs of the first light source unit 1, the second light source unit 21, and the second light source unit 22. As used herein, to “decrease the output” means limiting the output to a prescribed value or less. For example, to decrease the output may be either decreasing the output to make the radiation energy satisfy either Class 1 or Class 1M defined by JIS C 6802 or lowering the respective outputs of the first light source unit 1, the second light source unit 21, and the second light source unit 22 to zero by preventing a drive current from flowing through the first light source unit 1, the second light source unit 21, or the second light source unit 22. As used herein, the threshold value refers to a value that had been determined in advance based on the intensity of the detected light as detected by the detector 7 when the light-emitting system 100 was made to operate under the set of predetermined driving conditions before the light-emitting system 100 was shipped, for example. The intensity of the detected light that has been detected by the detector 7 decreases to less than the threshold value, for example, when at least one optical fiber, out of the first to fifth optical fibers F1-F5, is disconnected from its destination to cause leakage of the light.

The controller 15 updates, when the light-emitting system 100 is installed, the relation information stored in the storage device 16.

The functions of the controller 15 and the storage device 16 may be performed by a computer system. The computer system may include, for example, one or more input/output interfaces, one or more memories, and one or more processors (microprocessors). That is to say, the one or more processors may perform the functions of the controller 15 and the storage device 16 by executing one or more programs (applications) stored in the one or more memories. In this embodiment, the program is stored in advance in the memory of the controller 15. Alternatively, the program may also be downloaded via a telecommunications line such as the Internet or distributed after having been recorded in a non-transitory storage medium such as a memory card. Note that the input/output interface is an interface for inputting and outputting information to/from the controller 15 and includes a communications interface.

### (2.8) Selective Reflector

The selective reflector 10 transmits light, of which the wavelength is as long as the wavelength of the spontaneous emission of light produced by the first wavelength-converting element and light, of which the wavelength is as long as the wavelength of the spontaneous emission of light produced by the second wavelength-converting element, and reflects the excitation light P1. The selective reflector 10 reflects the excitation light P1 emerging from the first wavelength-converting member 4 and the second wavelength-converting member 5 without having its wavelength converted by the first wavelength-converting member 4 or the second wavelength-converting member 5. In this light-emitting system 100, the selective reflector 10 is provided between the second wavelength-converting member 5 and the light output member 6. In this light-emitting system 100, the second wavelength-converting member 5 and the selective reflector 10 are connected to each other via the sixth optical fiber F6. The seventh optical fiber F7 is connected to the other end, opposite from the sixth optical fiber F6, of the selective reflector 10. The seventh optical fiber F7 is held by the light output member 6.

### (2.9) Optical Multiplexer

The optical multiplexer 8 combines together the excitation light P1 coming from the first light source unit 1, the seed light ray P21 coming from the second light source unit 21, and the seed light ray P22 coming from the second light source unit 22 and outputs the combined light toward the first wavelength-converting member 4.

The optical multiplexer 8 may be, for example, a fiber-optic coupler. In the optical multiplexer 8, the first optical fiber F1 that propagates the excitation light P1 coming from the first light source unit 1, the second optical fiber F21 that propagates the seed light ray P21 coming from the second light source unit 21, the second optical fiber F22 that propagates the seed light ray P22 coming from the second light source unit 22, and the third optical fiber F3 that propagates light P4 including the excitation light P1, the seed light ray P21, and the seed light ray P22 are combined together by melting. The optical multiplexer 8 is configured to combine the excitation light P1, the seed light ray P21, and the seed light ray P22 together at a single point. However, this is only an example and should not be construed as limiting. Alternatively, the optical multiplexer 8 may also be configured to combine the excitation light P1, the second seed light ray P21, and the second seed light ray P22 in multiple stages such that a point where the excitation light P1 and the second seed light ray P21 are combined together is different from a point where the multiplexed light is further combined with the second seed light ray P22, for example.

The optical multiplexer 8 does not have to be a fiber-optic coupler but may also be, for example, a waveguide coupler or a multi-wavelength combiner. Alternatively, the optical multiplexer 8 may also include, in combination, a prism, a mirror, or a diffraction grating and a lens.

### (2.10) Optical Demultiplexer

The optical demultiplexer 9 branches, into the eighth optical fiber F8, the returning light P8 that has emerged from the second wavelength-converting member 5 toward the first wavelength-converting member 4 and propagated through the first wavelength-converting member 4 and the fourth optical fiber F4. The returning light P8 branched into the eighth optical fiber F8 is propagated by the eighth optical fiber F8 to be incident on the detector 7.

The optical demultiplexer 9 may be configured as an optical fiber. Alternatively, the optical demultiplexer 9 may also include, in combination, a prism, a mirror, or a diffraction grating and a lens.

### (2.11) Other Constituent Elements

The light-emitting system 100 includes a housing that houses at least the first light source unit 1 and the plurality of second light source units 2. If the light-emitting system 100 is used as a down light, for example, the housing may be installed, for example, on the floor of a building and behind its wall. A computer system that performs the functions of the controller 15 and the storage device 16 may be built in, for example, the housing that houses the first light source unit 1 and the plurality of second light source units 2.

In the light-emitting system 100, the first optical fiber F1, the plurality of second optical fibers F2, the optical multiplexer 8, the third optical fiber F3, the optical demultiplexer 9, the first wavelength-converting member 4, and the detector 7 may be further housed in the housing.

### (3) Operation of Light-Emitting System

In the light-emitting system 100, the controller 15 causes the first light source unit 1 to emit the excitation light P1 and causes the plurality of second light source units 2 to emit the seed light ray P21 and the seed light ray P22, respectively. Thus, in the light-emitting system 100, the excitation light P1 is allowed to be incident on the first optical fiber F1, the seed light ray P21 is allowed to be incident on the second optical fiber F21, and the seed light ray P22 is allowed to be incident on the second optical fiber F22. In the light-emitting system 100, the excitation light P1 propagated through the first optical fiber F1, the seed light ray P21 propagated through the second optical fiber F21, and the seed light ray P22 propagated through the second optical fiber F22 are combined together by the optical multiplexer 8. Then, the combined light is propagated through the third optical fiber F3, the optical demultiplexer 9, and the fourth optical fiber F4 to be incident on the first wavelength-converting member 4. In the light-emitting system 100, the light P5 emerging from the first wavelength-converting member 4 is mixed light in which the excitation light P1, the ASE produced from the first wavelength-converting element and having a wavelength of about 480 nm, and the seed light ray P2 amplified are mixed together. The two stimulated emissions of light P31, P32 corresponding one to one to the multiple seed light rays P21, P22 and having mutually different wavelengths may be, for example, green light and red light, respectively. In that case, the mixed light may be, for example, white light. In FIG. 3C, the lower stimulated emission of light P3 (P31) is green light and the upper stimulated emission of light P3 (P32) is red light.

The first wavelength-converting member 4 produces stimulated emission based on the spontaneous emission of light and the seed light ray P2. Thus, the excitation light P1 incident on the first wavelength-converting member 4 and the stimulated emission of light P3 that has been amplified by the stimulated emission emerge from the first wavelength-converting member 4. Of the light P5 emerging from the first wavelength-converting member 4 into the fifth optical fiber F5, the stimulated emission of light P3 having the same wavelength as the seed light ray P21 has a higher intensity than the seed light ray P21 incident on the first wavelength-converting member 4 from the second light source unit 21. On the other hand, of the light P5 emerging from the first wavelength-converting member 4 into the fifth optical fiber F5, the stimulated emission of light P3 having the same wavelength as the seed light ray P22 has a higher intensity than the seed light ray P22 incident on the first wavelength-converting member 4 from the second light source unit 22.

The light P5 emerging from the first wavelength-converting member 4 is propagated through the fifth optical fiber F5 to be incident on the second wavelength-converting member 5.

In the second wavelength-converting member 5, the second wavelength-converting element is excited by the excitation light P1, out of the excitation light P1, the seed light ray P21, and the seed light ray P22 included in the light P5 to produce light with a wavelength of 480 nm, light with a wavelength of 575 nm, light with a wavelength of 665 nm, and light with a wavelength of 750 nm. Thus, the second wavelength-converting member 5 produces light having a different wavelength from any one of the excitation light P1, the seed light ray P21, or the seed light ray P22. Thus, the light P6 emerging from the second wavelength-converting member 5 is propagated through the sixth optical fiber F6 to be incident on the selective reflector 10.

The selective reflector 10 may, for example, reflect light with a wavelength equal to or shorter than 460 nm and transmit visible light with a wavelength equal to or longer than 460 nm.

Thus, in the light-emitting system 100, out of the light P6 emerging from the second wavelength-converting member 5 toward the selective reflector 10, the light P7 transmitted through the selective reflector 10 is propagated by the seventh optical fiber F7 and output from the light output member 6. On the other hand, in the light-emitting system 100, the stimulated emission of light P3 produced by the second wavelength-converting member 5 and emerging from the light inlet portion 51 is superposed on the returning light P8 that has been reflected from the selective reflector 10. Thus, the returning light P8 is propagated by the fifth optical fiber F5, the first wavelength-converting member 4, and the fourth optical fiber F4, branched by the optical demultiplexer 9 into the eighth optical fiber F8, and propagated by the eighth optical fiber F8 to be incident on the detector 7.

In the light-emitting system 100, the controller 15 controls at least one of the first light source unit 1, the second light source unit 21, or the second light source unit 22 based on the intensity of the detected light that has been detected by the detector 7 and the relation information stored in the storage device 16.

### (4) Recapitulation

A light-emitting system 100 according to the first embodiment described above includes a first light source unit 1, a first wavelength-converting member 4, a second light source unit 2, a second wavelength-converting member 5, a light output member 6, and a detector 7. The first light source unit 1 emits excitation light P1. The first wavelength-converting member 4 is configured as an optical fiber containing a first wavelength-converting element. The first wavelength-converting element may be excited by excitation light P1 to produce a spontaneous emission of light having a longer wavelength than the excitation light P1 and may also be excited by an amplified spontaneous emission of light. The second light source unit 2 emits seed light ray P2 causing the first wavelength-converting element that has been excited by either the excitation light P1 or the amplified spontaneous emission of light to produce a stimulated emission of light P3. The second wavelength-converting member 5 contains a second wavelength-converting element. The second wavelength-converting element is excited by either the light produced by the first wavelength-converting element or light having a wavelength as long as the wavelength of the excitation light P1 to produce light having a wavelength different from both a wavelength of the excitation light P1 and a wavelength of the seed light ray P2. The light output member 6 outputs the light coming from the second wavelength-converting member 5. The detector 7 detects returning light P8 traveling from the first wavelength-converting member 4 toward the first light source unit 1 by way of a light guiding section 11 between the first light source unit 1 and the first wavelength-converting member 4.

The light-emitting system 100 according to the first embodiment may not only reduce an increase in the temperature of the light output member 6 but also detect the returning light P8.

In addition, in the light-emitting system 100 according to the first embodiment, the light output member 6 has no heat generation source such as the first light source unit 1, the second light source unit 21, the second light source unit 22, the first wavelength-converting member 4, or the second wavelength-converting member 5, thus reducing an increase in the temperature of the light output member 6. That is why in this light-emitting system 100, there is no need to provide any heat dissipating member for the light output member 6, thus contributing to reducing the size and weight of the light output member 6.

Furthermore, in the light-emitting system 100 according to the first embodiment, the controller 15 may control the respective outputs of the plurality of second light source units 2, thus enabling adjusting the respective intensities of a plurality of seed light rays P2 with multiple wavelengths and eventually adjusting the chromaticity of the light P7 output from the light output member 6.

Furthermore, in the light-emitting system 100 according to the first embodiment, the first wavelength-converting member 4 not only contains Pr³⁺ as the first wavelength-converting element to release an ASE in cyan but also makes a plurality of seed light rays P2 with multiple wavelengths incident on the first wavelength-converting member 4. This enables increasing the respective intensities of the stimulated emission of light in green and the stimulated emission of light in red. Thus, the light-emitting system 100 according to the first embodiment may improve the color rendering performance of the light P7 output from the light output member 6. Besides, in the light-emitting system 100 according to the first embodiment, the first wavelength-converting member 4 contains Pr³⁺ as the first wavelength-converting element and the second wavelength-converting member 5 contains Dy³⁺ as the second wavelength-converting element. Consequently, the light-emitting system 100 according to the first embodiment may further improve the color rendering performance of the light P7 output from the light output member 6.

### Second Embodiment

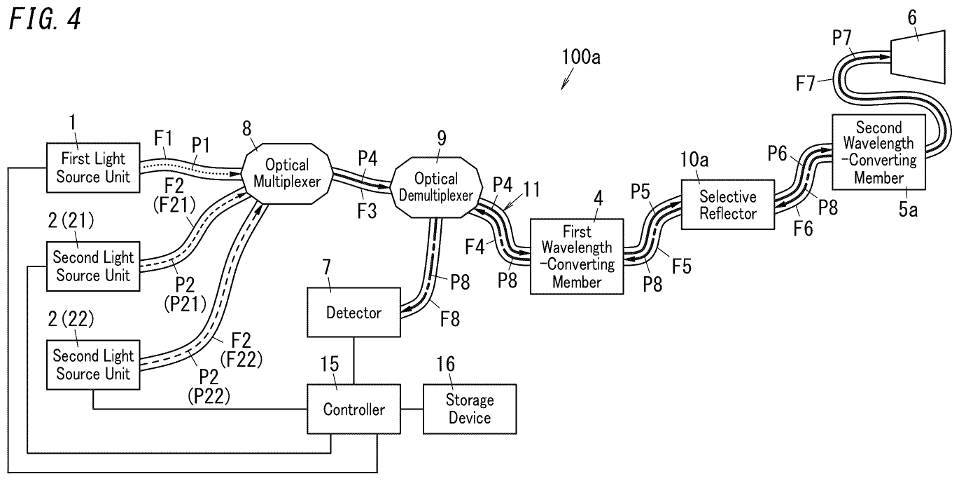

A light-emitting system 100a according to a second embodiment will be described with reference to FIG. 4. In the following description, any constituent element of the light-emitting system 100a according to this second embodiment, having the same function as a counterpart of the light-emitting system 100 according to the first embodiment described above, will be designated by the same reference numeral as that counterpart's, and description thereof will be omitted herein.

The light-emitting system 100a according to the second embodiment includes a second wavelength-converting member 5a and a selective reflector 10a instead of the second wavelength-converting member 5 and the selective reflector 10 of the light-emitting system 100 according to the first embodiment, which is a difference from the light-emitting system 100 according to the first embodiment.

The second wavelength-converting member 5a contains, as the second wavelength-converting element, Tb³⁺ instead of Dy³⁺ in the second wavelength-converting member 5 of the light-emitting system 100 according to the first embodiment, which is a difference from the second wavelength-converting member 5 of the light-emitting system 100 according to the first embodiment. In addition, the selective reflector 10a is provided between the first wavelength-converting member 4 and the second wavelength-converting member 5a, which is a difference from the selective reflector 10 of the light-emitting system 100 according to the first embodiment.

In the light-emitting system 100a according to the second embodiment, the first wavelength-converting member 4 and the selective reflector 10a are connected together via the fifth optical fiber F5, the selective reflector 10a and the second wavelength-converting member 5a are connected together via the sixth optical fiber F6, and the seventh optical fiber F7 is connected to the other end, opposite from the sixth optical fiber F6, of the second wavelength-converting member 5a.

The selective reflector 10a reflects the light having the wavelength of the excitation light P1 which is included in the light P5 coming from the first wavelength-converting member 4 and transmits the light (i.e., the stimulated emissions of light P31, P32) produced by the first wavelength-converting element.

The second wavelength-converting element of the second wavelength-converting member 5a is not excited by the excitation light P1 but is excited by the light produced by the first wavelength-converting element (e.g., light having a wavelength equal to or longer than 480 nm and equal to or shorter than 490 nm) to produce light, of which the wavelength is different from the wavelength of the excitation light P1 and the wavelength of the seed light ray P2. Tb³⁺ may be excited by absorbing an ASE produced from Pr³⁺ to produce an ASE having a wavelength unique to Tb³⁺.

The light output member 6 outputs the light P7 coming from the second wavelength-converting member 5a. The light P7 coming from the second wavelength-converting member 5a is propagated by the seventh optical fiber F7 to be output from the light output member 6 to the external space.

In the light-emitting system 100a according to the second embodiment, the returning light P8 returning from the second wavelength-converting member 5a toward the selective reflector 10a is transmitted through the selective reflector 10a. Thus, the returning light P8 propagated from the selective reflector 10a through the fourth optical fiber F4 and returning toward the first wavelength-converting member 4 includes the light produced by the second wavelength-converting member 5a and the excitation light P1. This returning light P8 is branched by the optical demultiplexer 9. Thus, the light-emitting system 100a, as well as the light-emitting system 100, allows the detector 7 to detect the returning light P8.

A light-emitting system 100a according to the second embodiment described above includes a first light source unit 1, a first wavelength-converting member 4, a second light source unit 2, a second wavelength-converting member 5a, a light output member 6, and a detector 7. The first light source unit 1 emits excitation light P1. The first wavelength-converting member 4 is an optical fiber containing a first wavelength-converting element. The first wavelength-converting element may be excited by excitation light P1 to produce a spontaneous emission of light having a longer wavelength than the excitation light P1 and may also be excited by an amplified spontaneous emission of light. The second light source unit 2 emits seed light ray P2 causing the first wavelength-converting element that has been excited by either the excitation light P1 or the amplified spontaneous emission of light to produce a stimulated emission of light P3. The second wavelength-converting member 5a contains a second wavelength-converting element. The second wavelength-converting element is excited by the light produced by the first wavelength-converting element to produce light having a wavelength different from both a wavelength of the excitation light P1 and a wavelength of the seed light rays P21, P22. The light output member 6 outputs the light coming from the second wavelength-converting member 5a. The detector 7 detects returning light P8 traveling from the first wavelength-converting member 4 toward the first light source unit 1 by way of a light guiding section 11 between the first light source unit 1 and the first wavelength-converting member 4. The detected light detected by the detector 7 may be, for example, light produced by the second wavelength-converting element which has a wavelength different from the wavelength of the excitation light P1 and the wavelength of the seed light rays P21, P22.

The light-emitting system 100a according to the second embodiment may not only reduce an increase in the temperature of the light output member 6 but also detect the returning light P8.

Besides, in the light-emitting system 100a according to the second embodiment, the first wavelength-converting member 4 contains Pr³⁺ as the first wavelength-converting element and the second wavelength-converting member 5a contains Tb³⁺ as the second wavelength-converting element. Consequently, the light-emitting system 100a according to the second embodiment may further improve the color rendering performance of the light P7 output from the light output member 6.

### Third Embodiment

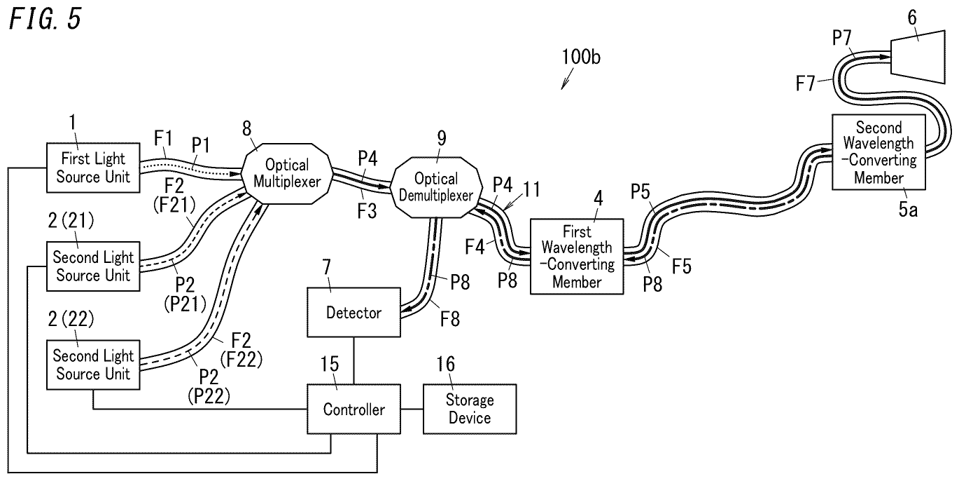

A light-emitting system 100b according to a third embodiment will be described with reference to FIG. 5. In the following description, any constituent element of the light-emitting system 100b according to this third embodiment, having the same function as a counterpart of the light-emitting system 100a according to the second embodiment described above, will be designated by the same reference numeral as that counterpart's, and description thereof will be omitted herein.

The light-emitting system 100b according to the third embodiment does not include the selective reflector 10a of the light-emitting system 100a according to the second embodiment, which is a difference from the light-emitting system 100a according to the second embodiment.

In the light-emitting system 100b according to the third embodiment, the first wavelength-converting member 4 and the second wavelength-converting member 5a are connected together via the fifth optical fiber F5, and the seventh optical fiber F7 is connected to the other end, opposite from the fifth optical fiber F5, of the second wavelength-converting member 5a.

The light-emitting system 100b according to the third embodiment, as well as the light-emitting system 100a according to the second embodiment, may not only reduce an increase in the temperature of the light output member 6 but also detect the returning light P8.

In addition, the light-emitting system 100b according to the third embodiment includes no selective reflector 10a, and therefore, allows a part of the excitation light P1 to be output from the light output member 6 as well.

### Fourth Embodiment

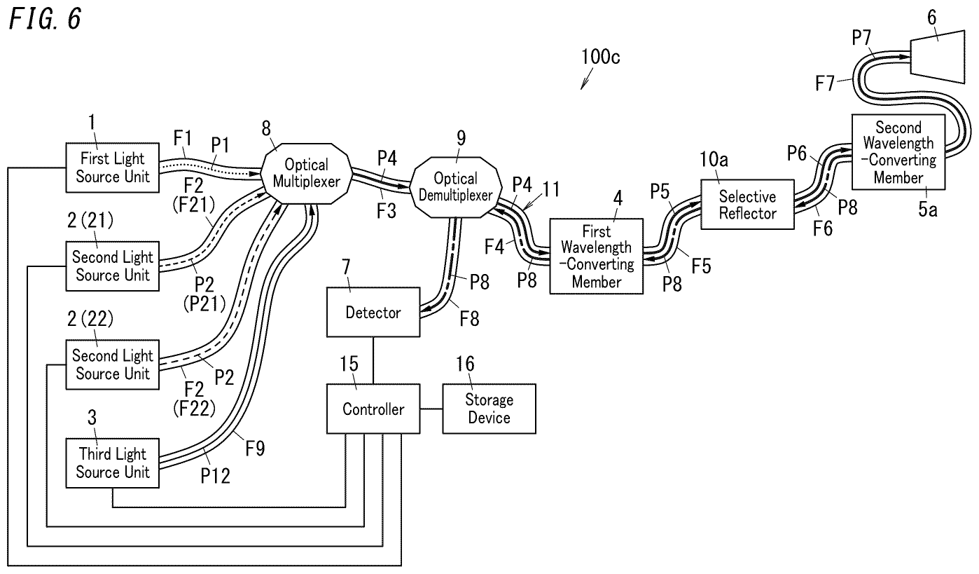

A light-emitting system 100c according to a fourth embodiment will be described with reference to FIG. 6. In the following description, any constituent element of the light-emitting system 100c according to this fourth embodiment, having the same function as a counterpart of the light-emitting system 100a according to the second embodiment described above, will be designated by the same reference numeral as that counterpart's, and description thereof will be omitted herein.

The light-emitting system 100c according to the third embodiment further includes a third light source unit 3, which is a difference from the light-emitting system 100a according to the second embodiment.

The third light source unit 3 emits second excitation light P12, of which the wavelength (e.g., 380 nm) is different from the wavelength (which may be equal to or longer than 440 nm and equal to or shorter than 450 nm) of first excitation light P1 that is the excitation light P1 emitted from the first light source unit 1. The second excitation light P12 is light that may excite the second wavelength-converting element. The third light source unit 3 may include, for example, a semiconductor laser diode that emits ultraviolet light.

The third light source unit 3 is connected to the optical multiplexer 8 via a ninth optical fiber F9. This allows the optical multiplexer 8 to combine together the first excitation light P1 coming from the first light source unit 1, the seed light ray P21 coming from the second light source unit 21, the seed light ray P22 coming from the second light source unit 22, and the second excitation light P12 coming from the third light source unit 3. Thus, the light P4 emerging from the optical multiplexer 8 may include the first excitation light P1, the seed light ray P21, the seed light ray P22, and the second excitation light P12.

In the light-emitting system 100c according to the fourth embodiment, when finding the intensity of the detected light that has been detected by the detector 7 less than a threshold value stored in the storage device 16, the controller 15 decreases the respective outputs of the first light source unit 1, the second light source unit 2, and the third light source unit 3. As used herein, the threshold value refers to a value that had been determined in advance based on the intensity of the detected light as detected by the detector 7 when the first light source unit 1, the second light source unit 21, the second light source unit 22, and the third light source unit 3 were driven under a set of predetermined driving conditions for the first light source unit 1, the second light source unit 21, the second light source unit 22, and the third light source unit 3. As used herein, to “decrease the output” means limiting the output to a prescribed value or less. For example, to decrease the output may be either decreasing the output to make the radiation energy satisfy either Class 1 or Class 1M defined by JIS C 6802 or lowering the respective outputs of the first light source unit 1, the second light source unit 21, the second light source unit 22, and the third light source unit 3 to zero by preventing a drive current from flowing through the first light source unit 1, the second light source unit 21, the second light source unit 22, or the third light source unit 3.

The light-emitting system 100c according to the fourth embodiment, as well as the light-emitting system 100a according to the second embodiment, may not only reduce an increase in the temperature of the light output member 6 but also detect the returning light P8.

### (Variations)

Note that the first to fourth embodiments described above are only exemplary ones of various embodiments of the present disclosure and should not be construed as limiting. Rather, the first to fourth exemplary embodiments may be readily modified in various manners depending on a design choice or any other factor without departing from the scope of the present disclosure.

For example, in the light-emitting systems 100, 100a, 100b, the controller 15 does not have to be configured to control the respective outputs of the first light source unit 1, the second light source unit 21, and the second light source unit 22 but may also be configured to control the output of at least one of the first light source unit 1, the second light source unit 21, or the second light source unit 22. Also, in the light-emitting system 100c, the controller 15 does not have to be configured to control the respective outputs of the first light source unit 1, the second light source unit 21, the second light source unit 22, and the third light source unit 3 but may also be configured to control the output of at least one of the first light source unit 1, the second light source unit 21, the second light source unit 22, or the third light source unit 3. If the first light source unit 1 or the second light source units 2 are subjected to pulsed flickering drive to adjust the chromaticity, the output of at least one of the first light source unit 1 or the second light source units 2 is preferably controlled, as the intensity of detected light, of which the wavelength is different from the wavelength of the excitation light P1 and the wavelength of the seed light ray P2, based on the intensity when the first light source unit 1 or the second light source units 2 is lit, not the average over its flickering period.

The laser light source included in the first light source unit 1 does not have to be a semiconductor laser diode that emits a blue laser beam but may also be, for example, a semiconductor laser diode that emits a violet laser beam. Furthermore, the first light source unit 1 does not have to include the semiconductor laser diode but may have a configuration including, for example, a light-emitting diode (LED) light source and an optical system.

The second light source unit 21 does not have to be a semiconductor laser diode that emits a green laser beam but may also be an LED that emits a green light ray. The second light source unit 22 does not have to be a semiconductor laser diode that emits a red laser beam but may also be an LED that emits a red light ray. Furthermore, the color of the light emitted from the second light source unit 2 does not have to be green or red but may also be, for example, orange, blue-green, or blue.

The light-emitting systems 100, 100a, 100b, 100c each include a plurality of second light source units 2. However, this is only an example and should not be construed as limiting. Rather, the light-emitting system 100, 100a, 100b, 100c may include at least one second light source unit 2.

Alternatively, in the light-emitting system 100, the second wavelength-converting member 5 and the light output member 6 may be directly connected to each other and the interface between the second wavelength-converting member 5 and the light output member 6 may also serve as the selective reflector 10. Likewise, in the light-emitting systems 100a, 100b, 100c, the second wavelength-converting member 5a and the light output member 6 may be directly connected to each other and the interface between the second wavelength-converting member 5a and the light output member 6 may also serve as the selective reflector 10.

Furthermore, in the light-emitting system 100, the selective reflector 10 does not have to be configured to reflect the excitation light P1 but may also be configured to, for example, reflect light having a wavelength equal to or longer than 650 nm and transmit visible light having a wavelength shorter than 650 nm out of the light produced by the first wavelength-converting element and having the wavelength of spontaneous emission of light and the light produced by the second wavelength-converting element and having the wavelength of spontaneous emission of light. In that case, in the light-emitting system 100, the light P7, transmitted through the selective reflector 10, of the light P6 is propagated by the seventh optical fiber F7 and output from the light output member 6. On the other hand, in the light-emitting system 100, the returning light P8 that has been reflected from the selective reflector 10 is propagated by the sixth optical fiber F6, the second wavelength-converting member 5, the fifth optical fiber F5, the first wavelength-converting member 4, and the fourth optical fiber F4, branched by the optical demultiplexer 9 into the eighth optical fiber F8, and propagated by the eighth optical fiber F8 to be incident on the detector 7.

Also, in the light-emitting system 100a, the selective reflector 10a is preferably configured as a grating of an optical fiber and the fifth optical fiber F5 between the first wavelength-converting member 4 and the second wavelength-converting member 5, the selective reflector 10a, and the sixth optical fiber F6 are preferably configured as a single optical fiber.

In the light-emitting system 100, each of the first to eighth optical fibers F1-F8 may be replaced with a different type of light guide member.

### (Aspects)

The first to fourth exemplary embodiments and their variations described above are specific implementations of the following aspects of the present disclosure.

A light-emitting system (100; 100a; 100b; 100c) according to a first aspect includes a first light source unit (1), a first wavelength-converting member (4), a second light source unit (2), a second wavelength-converting member (5; 5a), a light output member (6), and a detector (7). The first light source unit (1) emits excitation light (P1). The first wavelength-converting member (4) is an optical fiber containing a first wavelength-converting element. The first wavelength-converting element may be excited not only by the excitation light (P1) to produce a spontaneous emission of light having a longer wavelength than the excitation light (P1) but also by an amplified spontaneous emission of light. The second light source unit (2) emits a seed light ray (P2) causing the first wavelength-converting element that has been excited by either the excitation light (P1) or the amplified spontaneous emission of light to produce a stimulated emission of light (P3). The second wavelength-converting member (5; 5a) contains a second wavelength-converting element. The second wavelength-converting element is excited by either light produced by the first wavelength-converting element or the excitation light (P1) to produce light having a wavelength different from both a wavelength of the excitation light (P1) and a wavelength of the seed light ray (P2). The light output member (6) outputs the light coming from the second wavelength-converting member (5; 5a). The detector (7) detects returning light (P8) traveling from the first wavelength-converting member (4) toward the first light source unit (1) by way of a light guiding section (11) between the first light source unit (1) and the first wavelength-converting member (4).

The light-emitting system (100; 100a; 100b; 100c) according to the first aspect may not only reduce an increase in the temperature of the light output member (6) but also detect the returning light (P8).

A light-emitting system (100; 100a; 100b; 100c) according to a second aspect, which may be implemented in conjunction with the first aspect, further includes a controller (15). The controller (15) controls output of at least one of the first light source unit (1) or the second light source unit (2).

The light-emitting system (100; 100a; 100b; 100c) according to the second aspect may adjust the chromaticity of the light output from the light output member (6).

In a light-emitting system (100; 100a; 100b; 100c) according to a third aspect, which may be implemented in conjunction with the second aspect, the controller (15) controls the output of at least one of the first light source unit (1) or the second light source unit (2) based on intensity of detected light. The detected light forms part of the returning light (P8) incident on the detector (7). The detected light has a wavelength different from both the wavelength of the excitation light (P1) and the wavelength of the seed light ray (P2).

The light-emitting system (100; 100a; 100b; 100c) according to the third aspect may reduce a variation with time in the chromaticity of the light output from the light output member (6).

A light-emitting system (100; 100a; 100b; 100c) according to a fourth aspect, which may be implemented in conjunction with the third aspect, further includes a storage device (16). The storage device (16) stores, in advance, relation information about a relation between a set of conditions for driving the first light source unit (1) and the second light source unit (2) and the intensity of the detected light as detected by the detector (7). The controller (15) controls at least one of the first light source unit (1) or the second light source unit (2) in accordance with the intensity of the detected light as detected by the detector (7) and the relation information stored in the storage device (16).

The light-emitting system (100; 100a; 100b; 100c) according to the fourth aspect may reduce a variation with time in the chromaticity of the light output from the light output member (6).

A light-emitting system (100c) according to a fifth aspect, which may be implemented in conjunction with the fourth aspect, further includes a third light source unit (3). The third light source unit (3) emits second excitation light (P12) having a different wavelength from first excitation light (P1) that is the excitation light (P1) emitted from the first light source unit (1). The second excitation light (P12) may excite the second wavelength-converting element.

The light-emitting system (100c) according to the fifth aspect may have the second wavelength-converting element excited by the second excitation light (P12), thus eliminating the need to use the light produced by the first wavelength-converting element to excite the second wavelength-converting element.

In a light-emitting system (100c) according to a sixth aspect, which may be implemented in conjunction with the fifth aspect, when the intensity of the detected light as detected by the detector (7) decreases to less than a threshold value stored in the storage device (16), the controller (15) decreases respective outputs of the first light source unit (1), the second light source unit (2), and the third light source unit (3).

The light-emitting system (100c) according to the sixth aspect may decrease the respective outputs of the first light source unit (1), the second light source unit (2), and the third light source unit (3) when there may be some leakage of light.

In a light-emitting system (100; 100a; 100b; 100c) according to a seventh aspect, which may be implemented in conjunction with any one of the fourth to sixth aspects, when the light-emitting system (100; 100a; 100b; 100c) is installed, the controller (15) updates the relation information stored in the storage device (16).

The light-emitting system (100; 100a; 100b; 100c) according to the seventh aspect may update the relation information at the time of installation of the light-emitting system (100; 100a; 100b; 100c).

In a light-emitting system (100; 100a; 100b; 100c) according to an eighth aspect, which may be implemented in conjunction with any one of the third to seventh aspects, the detected light is a light ray having a wavelength that is one of multiple wavelengths of a plurality of light rays produced by the second wavelength-converting element. The detected light has a wavelength equal to or longer than 650 nm.

The light-emitting system (100; 100a; 100b; 100c) according to the eighth aspect may use, as the detected light, light having a wavelength that is not used for adjusting the color.

A light-emitting system (100) according to a ninth aspect, which may be implemented in conjunction with any one of the first to seventh aspects, further includes a selective reflector (10). The selective reflector (10; 10a) transmits light having a wavelength as long as a wavelength of the spontaneous emission of light produced by the first wavelength-converting element and reflects the excitation light (P1).

The light-emitting system (100; 10a) according to the ninth aspect may prevent the excitation light (P1) from being output from the light output member (6).

In a light-emitting system (100; 100a; 100b; 100c) according to a tenth aspect, which may be implemented in conjunction with any one of the first to ninth aspects, the first light source unit (1) includes a laser light source.

The light-emitting system (100; 100a; 100b; 100c) according to the tenth aspect may increase the intensity of the excitation light (P1).

A light-emitting system (100; 100a; 100b; 100c) according to an eleventh aspect, which may be implemented in conjunction with any one of the first to tenth aspects, includes a plurality of the second light source units (2). The plurality of the second light source units (2) respectively emit a plurality of the seed light rays (P21, P21). The plurality of the seed light rays (P21, P22) emitted from the plurality of the second light source units (2) have mutually different wavelengths.

The light-emitting system (100; 100a; 100b; 100c) according to the eleventh aspect allows light, including multiple stimulated emissions of light (P31, P32) corresponding one to one to the plurality of the seed light rays (P21, P22), to be output from the light output member (6).

In a light-emitting system (100; 100a; 100b; 100c) according to a twelfth aspect, which may be implemented in conjunction with any one of the first to eleventh aspects, the first wavelength-converting element and the second wavelength-converting element each include an element selected from the group consisting of Pr, Tb, Ho, Dy, Er, Eu, Nd, and Mn.

The light-emitting system (100; 100a; 100b; 100c) according to the twelfth aspect may have, for example, the second wavelength-converting element excited by the amplified spontaneous emission of light produced from the first wavelength-converting element, thus causing the second wavelength-converting element to produce an amplified spontaneous emission of light having a different wavelength from the amplified spontaneous emission of light produced from the first wavelength-converting element.

Reference Signs List

| | |
|---|---|
| 1 | First Light Source Unit |
| 2 | Second Light Source Unit |
| 21 | Second Light Source Unit |
| 22 | Second Light Source Unit |
| 3 | Third Light Source Unit |
| 4 | First Wavelength-Converting Member |
| 5, 5a | Second Wavelength-Converting Member |
| 6 | Light Output Member |
| 7 | Detector |
| 8 | Optical Multiplexer |
| 9 | Optical Demultiplexer |
| 10, 10a | Selective Reflector |
| 11 | Light Guiding Section |
| 15 | Controller |
| 16 | Storage Device |
| 100, 100a, 100b, 100c | Light-Emitting System |
| P1 | Excitation Light |
| P12 | Second Excitation Light |
| P2 | Seed Light |
| P21 | Seed Light |
| P22 | Seed Light |
| P3 | Stimulated Emission of Light |
| P4 | Light |
| P5 | Light |
| P6 | Light |
| P7 | Light |
| P8 | Returning Light |

1. A light-emitting system comprising:
a first light source unit configured to emit excitation light;
a first wavelength-converting member configured as an optical fiber containing a first wavelength-converting element, the first wavelength-converting element being able to be excited by not only the excitation light to produce a spontaneous emission of light having a longer wavelength than the excitation light but also by an amplified spontaneous emission of light;
a second light source unit configured to emit a seed light ray causing the first wavelength-converting element that has been excited by either the excitation light or the amplified spontaneous emission of light to produce a stimulated emission of light;
a second wavelength-converting member containing a second wavelength-converting element, the second wavelength-converting element being excited by either light produced by the first wavelength-converting element or the excitation light to produce light having a wavelength different from both a wavelength of the excitation light and a wavelength of the seed light ray;
a light output member configured to output the light coming from the second wavelength-converting member; and
a detector configured to detect returning light traveling from the first wavelength-converting member toward the first light source unit by way of a light guiding section between the first light source unit and the first wavelength-converting member.

2. The light-emitting system of claim 1, further comprising a controller configured to control output of at least one of the first light source unit or the second light source unit.

3. The light-emitting system of claim 2, wherein
the controller is configured to control the output of at least one of the first light source unit or the second light source unit based on intensity of detected light, the detected light forming part of the returning light incident on the detector, the detected light having a wavelength different from both the wavelength of the excitation light and the wavelength of the seed light ray.

4. The light-emitting system of claim 3, further comprising a storage device configured to store, in advance, relation information about a relation between a set of conditions for driving the first light source unit and the second light source unit and the intensity of the detected light as detected by the detector, wherein
the controller is configured to control at least one of the first light source unit or the second light source unit in accordance with the intensity of the detected light as detected by the detector and the relation information stored in the storage device.

5. The light-emitting system of claim 4, further comprising a third light source unit configured to emit second excitation light having a different wavelength from first excitation light, the first excitation light being the excitation light emitted from the first light source unit, wherein
the second excitation light is able to excite the second wavelength-converting element.

6. The light-emitting system of claim 5, wherein
the controller is configured to, when the intensity of the detected light as detected by the detector decreases to less than a threshold value stored in the storage device, decrease respective outputs of the first light source unit, the second light source unit, and the third light source unit.

7. The light-emitting system of claim 4, wherein
the controller is configured to, when the light-emitting system is installed, update the relation information stored in the storage device.

8. The light-emitting system of claim 3, wherein
the detected light is a light ray having a wavelength that is one of multiple wavelengths of a plurality of light rays produced by the second wavelength-converting element, and
the detected light has a wavelength equal to or longer than 650 nm.

9. The light-emitting system of claim 1, comprising a selective reflector configured to transmit light having a wavelength as long as a wavelength of the spontaneous emission of light produced by the first wavelength-converting element and reflect the excitation light.

10. The light-emitting system of claim 1, wherein
the first light source unit includes a laser light source.

11. The light-emitting system of claim 1, wherein
the light-emitting system includes a plurality of the second light source units,
the plurality of the second light source units are configured to respectively emit a plurality of the seed light rays, and
the plurality of the seed light rays emitted from the plurality of the second light source units have mutually different wavelengths.

12. The light-emitting system of claim 1, wherein
the first wavelength-converting element and the second wavelength-converting element each include an element selected from the group consisting of Pr, Tb, Ho, Dy, Er, Eu, Nd, and Mn.
